(19) United States
(12) Patent Application Publication
(10) Pub. No.: US 2025/0144890 A1
(43) Pub. Date: May 8, 2025

(54) JOINT BODY, SEMICONDUCTOR DEVICE EQUIPPED WITH JOINT BODY, AND JOINT BODY PRODUCTION METHOD

(71) Applicant: Mitsubishi Electric Corporation, Tokyo (JP)

(72) Inventor: Tatsuya KITAGAWA, Chiyoda-ku, Tokyo (JP)

(73) Assignee: Mitsubishi Electric Corporation, Tokyo (JP)

(21) Appl. No.: 18/836,006

(22) PCT Filed: Feb. 13, 2023
(86) PCT No.: PCT/JP2023/004742

§ 371 Date: Aug. 6, 2024

(30) Foreign Application Priority Data
Feb. 16, 2022 (JP) 2022-021836

(51) Int. Cl. B29C 65/44; B23K 26/352; H01L 23/00; H01L 23/31

(52) U.S. Cl. CPC B29C 65/44; B23K 26/352; H01L 23/3135; H01L 24/48; H01L 2224/48245

(57) ABSTRACT

A joint body of the present disclosure includes a metal member and a resin member joined to the metal member, the metal member has a dendritic structure portion on a surface joined to the resin member, at least a part of the dendritic structure portion has a nanometer-order diameter, and the resin member permeates through the dendritic structure portion. Such a configuration can ensure an adequate contact area between the resin member and the nanometer-order dendritic structure portion formed on the metal member, so that it is possible to obtain a joint body in which the metal member and the resin member are firmly joined together.

### TECHNICAL FIELD

The present disclosure relates to a joint body, a semiconductor device equipped with a joint body, and a joint body production method.

### BACKGROUND ART

As a technique to enhance joining performance between a metal member and a resin member, a technique to form a thin film made of functional molecules such as a silane coupling agent on a surface of the metal member by vapor deposition treatment or the like to enhance adhesion with the resin is known. It is, however, required for such a method to separately prepare the functional molecules, and furthermore, in order to form the thin film made of the functional molecules only at a necessary site, it is necessary to prevent contamination by means of masking, so that the treatment process becomes complicated. Therefore, a dissimilar material joint body of a metal member and a resin member obtained by enhancing joining performance using the functional molecules becomes high in cost.

Therefore, as a technique that need not separately require a raw material made of functional molecules or a mask, many direct joining techniques using an anchor (anchoring) effect obtained by causing a resin member to permeate through projections and depressions formed on a metal member have been proposed. Specifically, a metal member or a plated surface is irradiated with a laser, and the energy of the laser irradiation vaporizes and removes metal molecules on the surface to form projections and depressions. It is possible to obtain a dissimilar material joint body having higher joint strength by causing a resin member to enter the depressions thus formed. This eliminates the need of separate preparation of a raw material made of functional molecules or a mask, and it is a simple treatment process, so that it is possible to manufacture a dissimilar material joint body having higher joint strength at a lower cost than before.

For example, as one known technique, PTL 1 discloses a joining technique for obtaining an anchor effect and a covalent bonding effect by providing micrometer-order depressions on a surface of a metal to be joined to a polymer material, the depressions having projections on their respective inner walls, and forming nanometer-order pores or depressions on the surfaces of the projections.

### CITATION LIST

### Patent Literature

PTL 1: Japanese National Patent Publication No. 2019-528182

### SUMMARY OF INVENTION

### Technical Problem

Although the depressions provided on the surface of the metal require a depth of greater than or equal to five times a width of each depression, a short pulsed or ultrashort pulsed laser used for processing is not suitable for forming deep depressions and requires time for processing, which is not impractical in terms of production efficiency. Further, as described above, the covalent bonding effect can be obtained by nanometer-order pores or depressions formed on the surfaces of the projections, but there is nothing special about the formation of nanometer-order projections and depressions or the like as surface roughness on the surface of the metal. Rather, the pores or depressions formed on the surfaces of the projections do not achieve an adequate contact area between the metal material and the polymer material, so that a joining effect produced by the nanometer-order structure portion is not adequate.

### Solution to Problem

A joint body of a metal member and a resin member according to the present disclosure includes a metal member and a resin member joined to the metal member, the metal member has a dendritic structure portion on a surface joined to the resin member, at least a part of the dendritic structure portion has a nanometer-order diameter, and the resin member permeates through the dendritic structure portion.

Further, a semiconductor device according to one aspect of the present disclosure is a semiconductor device including a surface electrode, a conductive layer, an electrode terminal, or a wire, the surface electrode, the conductive layer, the electrode terminal, or the wire being encapsulated in a resin member, in which the surface electrode, the conductive layer, the electrode terminal, or the wire are metal members, in at least a part of a joint body of the surface electrode, the conductive layer, the electrode terminal, or the wire member and the resin member, the surface electrode, the conductive layer, the electrode terminal, or the wire member has a dendritic structure portion on a surface joined to the resin member, at least a part of the dendritic structure portion has a nanometer-order diameter, and the resin member permeates through the dendritic structure portion.

Further, a resin-metal joint body production method according to one aspect of the present disclosure includes a surface treatment process of forming a first depression and a dendritic structure portion on a surface of a metal member, at least a part of the dendritic structure portion having a nanometer-order diameter, and a joining process of causing a resin member to permeate through the dendritic structure portion to join the metal member and the resin member together.

### Advantageous Effects of Invention

According to the present disclosure, it is possible to ensure an adequate contact area between the resin member and the nanometer-order dendritic structure portion formed on the metal member, so that it is possible to obtain a resin-metal joint body in which the metal member and the resin member are firmly joined together.

### BRIEF DESCRIPTION OF DRAWINGS

FIG. 1 is a schematic cross-sectional view of a joint body according to a first embodiment.

FIG. 2 is a schematic cross-sectional view of the joint body according to the first embodiment along a production process.

FIG. 3 is an SEM image of a surface of a metal member 101 after irradiation with a pulsed laser.

FIG. 4 is an enlarged SEM image of the surface of metal member 101 after irradiation with a pulsed laser.

FIG. 5 is an SEM image of a cross section of metal member 101 after irradiation with a pulsed laser.

FIG. 6 is a TEM image of the cross section of metal member 101 after irradiation with a pulsed laser.

FIG. 7 is a result of cross-sectional analysis performed on metal member 101 after irradiation with a laser having an energy density of 20 J/cm². FIG. 7(a) is a cross-sectional TEM image, FIG. 7(b) is a result of cross-sectional TEM-EDX analysis showing distribution of Al element, and FIG. 7(c) is a result of cross-sectional TEM-EDX analysis showing distribution of O element.

FIG. 8 is a result of cross-sectional analysis performed on metal member 101 after irradiation with a laser having an energy density of 50 J/cm². FIG. 8(a) is a cross-sectional TEM image, FIG. 8(b) is a result of cross-sectional TEM-EDX analysis showing distribution of Al element, and FIG. 8(c) is a result of cross-sectional TEM-EDX analysis showing distribution of O element.

FIG. 9 is a cross-sectional SEM image of a joint body subjected to fatigue strength testing. FIG. 9(a) is a cross-sectional SEM image of a joint body manufactured as an example, and FIG. 9(b) is a cross-sectional SEM image of a joint body manufactured as a comparative example.

FIG. 10 is a schematic cross-sectional view of a joint body according to a second embodiment.

FIG. 11 is an SEM image of a surface of a metal member 101 according to the second embodiment.

FIG. 12 is a TEM image of a cross section of a first depression 103 of metal member 101 according to the second embodiment.

FIG. 13 is a schematic cross-sectional view of a joint body 120 according to a third embodiment.

FIG. 14 is an SEM image of a cross section of a surface of a metal member 101 obtained in the third embodiment.

FIG. 15 is a TEM image of a cross section of a first depression 103 of metal member 101 obtained in the third embodiment.

FIG. 16 is a schematic cross-sectional view of a semiconductor device 200 according to a fourth embodiment.

### DESCRIPTION OF EMBODIMENTS

With reference to the drawings, embodiments of the present disclosure will be described below. Note that the present disclosure is not limited to the following embodiments. Further, in order to clarify the description, the drawings are simplified as needed, and repetition of the description may be omitted.

### First Embodiment

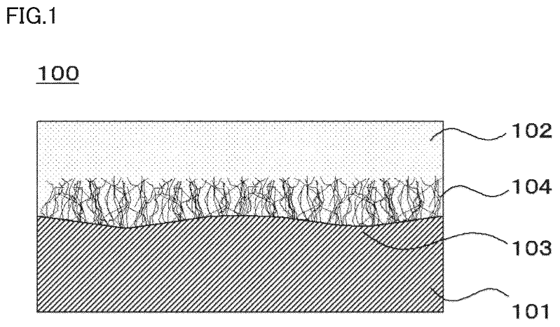

FIG. 1 is a schematic cross-sectional view of a joint body according to a first embodiment.

As illustrated in FIG. 1, a joint body 100 is a joint body of a metal member 101 and a resin member 102, and a first depression 103 and a dendritic structure portion 104 that is mainly formed of metal member 101 are formed on a surface, that is a joining portion, of metal member 101. A plurality of first depressions 103 are formed on a surface joined to resin member 102, and dendritic structure portion 104 is formed on a surface of each first depression 103. Dendritic structure portion 104 includes a dendritic body, at least a part of the dendritic body having a nanometer-order diameter of greater than or equal to 1 nm and less than 10 nm, and spatially spreads so as to cause dendritic bodies adjacent to each other to intertwine. Furthermore, resin member 102 permeates through the dendritic bodies that spatially spread. Metal member 101 is, for example, pure metal such as Al, Cu, or Fe. Alternatively, metal member 101 is an alloy containing at least one of Al, Cu, Fe, Ni, Au, Pd, Ag, or Sn as a main component. In the first embodiment, a case where an alloy containing Al as a main component is used will be given as an example. Note that the main component refers to a component that is greater than or equal to 50% by weight ratio in all metal member 101. Resin member 102 may be any resin member as long as the resin member can permeate through dendritic structure portion 104, and examples of the resin member include an epoxy resin, silicone, nylon, urethane, and a poly phenylene sulfide resin. Furthermore, a depth of first depression 103 to a bottom is preferably in a range of greater than or equal to 100 nm and less than or equal to 10 μm, and a ratio of the depth to a width of first depression 103 is preferably greater than or equal to 0.002 and less than or equal to 0.2. Further, a thickness of dendritic structure portion 104 is preferably in a range of greater than or equal to 1/1000 and less than or equal to 1/100 of the width of first depression 103, and furthermore, the thickness of dendritic structure portion 104 is preferably in a range of greater than or equal to 1/100 and less than or equal to 1/10 of the depth of first depression 103.

In joint body 100 configured as described above, resin member 102 permeates through dendritic structure portion 104, so that it is possible to ensure an adequate contact area between resin member 102 and dendritic structure portion 104. Further, molecules constituting resin member 102 and molecules constituting dendritic structure portion 104 come close to each other on the order of nanometers to produce an intermolecular force, so that resin member 102 and dendritic structure portion 104 are firmly joined together.

As described above, the configuration given in the first embodiment makes it possible to obtain a resin-metal joint body having higher strength and longer durability without using functional molecules or the like while suppressing a decrease in productivity due to formation of a structure for obtaining an anchor effect.

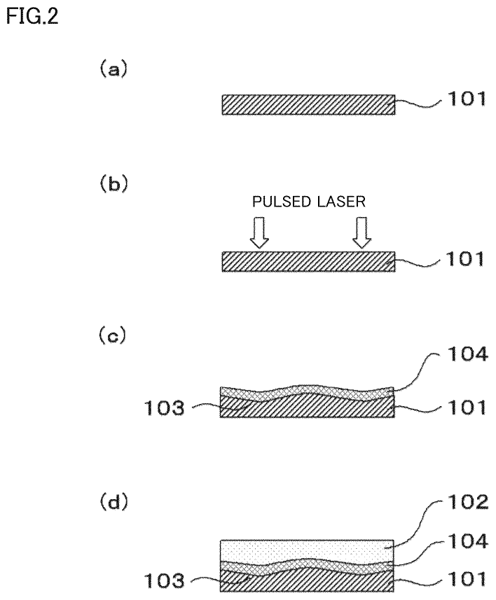

Next, a joint body production process according to the first embodiment will be described. FIGS. 2(a) to (d) are each a schematic cross-sectional view of the joint body according to the first embodiment along the production process.

First, as illustrated in FIG. 2 (a), metal member 101 is prepared. Metal member 101 is, for example, pure metal such as Al, Cu, or Fe. Alternatively, metal member 101 is an alloy containing at least one of Al, Cu, Fe, Ni, Au, Pd, Ag, or Sn as a main component. The surface of metal member 101 may be subjected to plating treatment such as Ni plating or Cu plating, or stabilization treatment such as a chromate treatment or alumite treatment. Furthermore, if necessary, the surface of metal member 101 may be subjected to pretreatment such as plasma treatment, corona treatment, or ultraviolet irradiation treatment before the stabilization treatment. As a result, the surface to be joined is cleaned to become a uniform metal member surface.

Therefore, in the production process, FIG. 2(a) is regarded as a preparation process.

Next, as illustrated in FIG. 2(b), the surface of metal member 101 is irradiated with a laser to form first depression 103 and dendritic structure portion 104 on the surface of metal member 101. The laser with which irradiation is performed is preferably a pulsed laser, and a pulse width is preferably as short as possible from the viewpoint of avoiding the surface of metal member 101, first depression 103, and dendritic structure portion 104 from being deformed or the like due to heat. More specifically, the pulse width is preferably less than or equal to 10 ns, but an equipment cost increases as the pulse width decreases, and it is therefore possible to make selection considering a balance with productivity. Further, a wavelength of the pulsed laser is not particularly limited, but as an example of the wavelength suitable for metal processing, a wavelength of greater than or equal to 200 nm and less than or equal to 10,000 nm is preferable, and a wavelength of greater than or equal to 400 nm and less than or equal to 2,000 nm is more preferable. Further, energy density of the pulsed laser emitted per unit area is preferably in a range of greater than or equal to 0.5 J/cm² and less than or equal to 50 J/cm². Furthermore, the energy density is more preferably in a range of greater than or equal to 5 J/cm² and less than or equal to 30 J/cm². In a case where the energy density is less than 5 J/cm², the amount of energy being supplied is too small to form first depression 103, so that dendritic structure portion 104 is not formed. On the other hand, in a case where the energy density is greater than 30 J/cm², the energy being supplied becomes excessive to cause dendritic structure portion 104 to melt, and only first depression 103 is formed. Further, if necessary, the laser irradiation may be performed in a gas atmosphere such as N₂, Ar, or He. The laser irradiation performed under an atmosphere of inert gas can inhibit, for example, metal member 101, and first depression 103 and dendritic structure portion 104 from being subject to oxidation, so that it is also applicable to control of wettability of metal member 101, and first depression 103 and dendritic structure portion 104 after the laser irradiation. Furthermore, for the purpose of cooling, it is also possible to perform the laser irradiation while supplying an inert gas.

Therefore, in the production process, FIG. 2(b) is regarded as a surface treatment process.

FIG. 2(c) is a cross-sectional view of metal member 101, first depression 103, and dendritic structure portion 104 with first depression 103 and dendritic structure portion 104 formed on the surface of metal member 101 by irradiation with a pulsed laser. When the surface of metal member 101 is irradiated with a laser, metal member 101 is partially melted or vaporized by ablation. Metal member 101 is partially melted or vaporized by ablation to form first depression 103, and dendritic structure portion 104 is formed on first depression 103. Dendritic structure portion 104 includes a dendritic body, at least a part of the dendritic body having a nanometer-order diameter of greater than or equal to 1 nm and less than 10 nm, and spatially spreads so as to cause dendritic bodies adjacent to each other to intertwine. Further, the laser irradiation is performed on metal member 101 at intervals that can be controlled by performing irradiation while moving a laser light source with a galvano lens or the like.

It is preferable that a relative position between laser-irradiation spots be set such that a distance between diameter centers of adjacent spots falls within a range of 1 time to 5 times the diameter of each laser-irradiation spot. For example, in a case where the distance is equal to 1 time, the laser spots are positioned in contact with each other without a gap, thereby causing the spots to spread over without a gap.

Therefore, in the production process, FIG. 2(c) illustrates a state after the surface treatment process.

FIG. 2(d) illustrates a schematic cross-sectional view of joint body 100 obtained by joining resin member 102 to metal member 101 on which first depression 103 and dendritic structure portion 104 are formed. Examples of resin member 102 include, but not particularly limited to, an epoxy resin, silicone, nylon, urethane, and polyphenylene sulfide (PPS). In order to join metal member 101 and resin member 102 together, resin member 102 partially or entirely melted is joined to the surface of metal member 101 and the surface of first depression 103 on which dendritic structure portion 104 is formed. Dendritic structure portion 104 includes dendritic bodies, at least a part of each dendritic body having a nanometer-order diameter, and resin member 102 permeates through the dendritic bodies, so that it is possible to obtain joint body 100 having higher strength and longer durability.

Therefore, in the production process, FIG. 2(d) is regarded as a joining process.

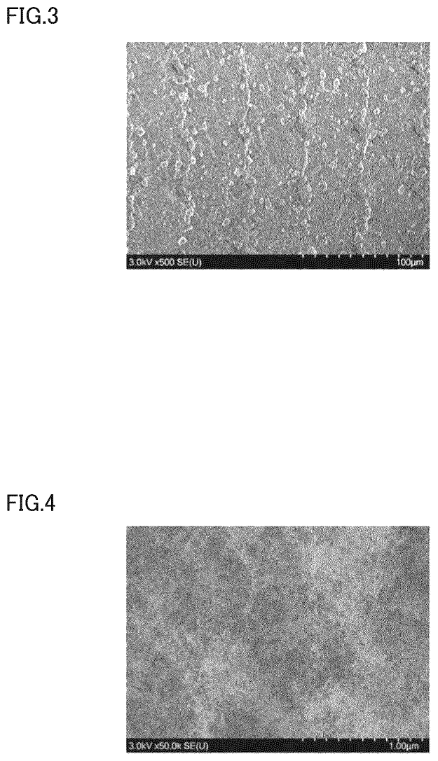

Next, FIGS. 3 to 8 each show a result of observing the surface and cross section. of metal member 101 obtained in the first embodiment.

FIG. 3 is an example of a scanning electron microscope image (SEM image) of the surface of metal member 101 after irradiation with a pulsed laser. As a result of laser irradiation performed at a distance equal to the diameter of the laser-irradiation spot, in other words, at a distance of 1 time the diameter of the spot, first depressions 103 formed by the laser irradiation form surfaces that are adjacent to each other but do not overlap each other, and are in contact with each other without a gap.

FIG. 4 is an example of an enlarged scanning electron microscope image (SEM image) of the surface of metal member 101 after irradiation with a pulsed laser. From

FIG. 4, it can be seen that dendritic structure portion 104 is formed on first depression 103 formed on the surface of metal member 101. At least a part of each dendritic body constituting dendritic structure portion 104 have a diameter of about several nm, and the dendritic bodies spatially spread so as to cause dendritic bodies adjacent to each other to intertwine. The laser irradiation interval is not particularly limited, but irradiation performed at intervals of from 1.0 times to 5.0 times the diameter of the spot forms dendritic structure portion 104 on the surface of first depression 103, and resin member 102 permeates through dendritic structure portion 104, so that it is possible to form strong joint body 100 of metal member 101 and resin member 102. Note that, in a case where laser irradiation is performed at intervals of greater than or equal to 1.0 times, dendritic structure portion 104 can also be formed on a surface of metal member 101 that is located around first depression 103 and has not been irradiated with a laser.

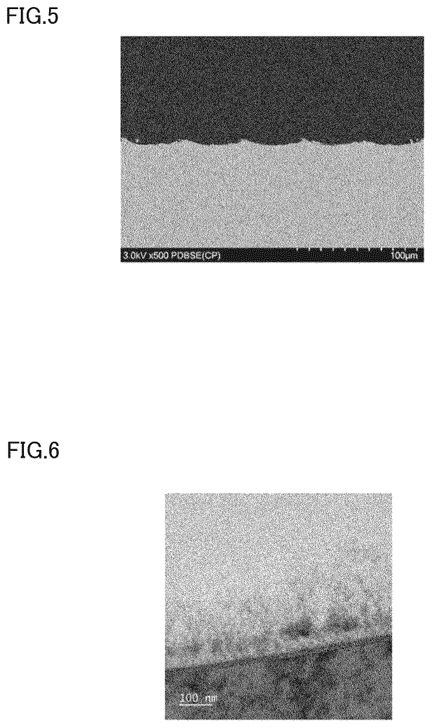

FIG. 5 is an example of a scanning electron microscope image (SEM image) of the cross section of metal member 101 after irradiation with a pulsed laser. Further, FIG. 6 is an example of a transmission electron microscope image (TEM image) of the cross section of metal member 101 after irradiation with a pulsed laser. From FIGS. 5 and 6, it can be seen that first depressions 103 adjacent to each other do not overlap each other but are in contact with each other without a gap, and dendritic structure portion 104 having a thickness of about several 100 nm from the surface of first depression 103 is formed on the surface of first depression 103.

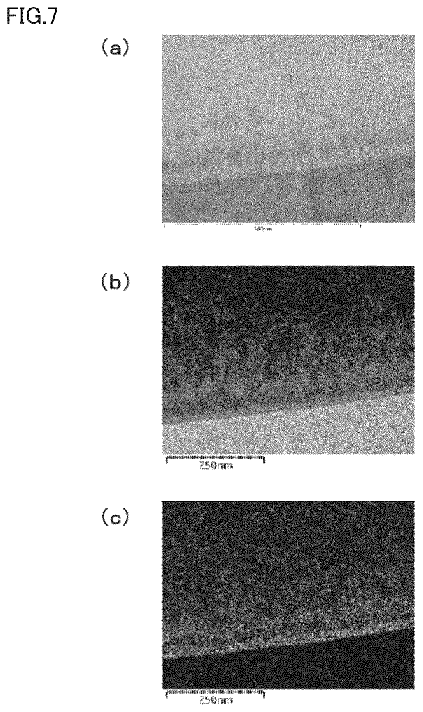

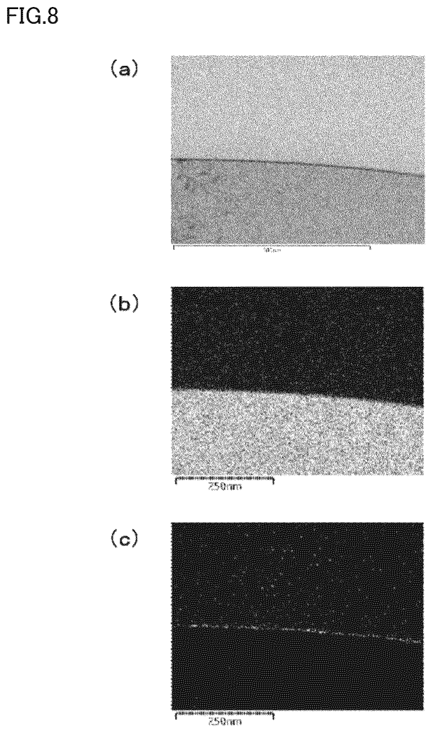

FIGS. 7(a) to 7(c) and FIGS. 8(a) to 8(c) are comparison results of cross-sectional TEM-energy dispersive X-ray spectroscopy (EDX) analysis on, using Al as metal member 101, metal member 101 after irradiation with a pulsed laser under two conditions having different energy densities.

First, FIGS. 7(a) to 7(c) are results of cross-sectional analysis on metal member 101 after irradiation with a laser having an energy density of 20 J/cm². FIG. 7(a) shows a result of cross-sectional TEM analysis, FIG. 7(b) shows a result of cross-sectional TEM-EDX analysis showing distribution of Al element, and FIG. 7(c) shows a result of cross-sectional TEM-EDX analysis showing distribution of O element. The results shown in FIGS. 7(a) to 7(c) show that in a case where irradiation with a laser having an energy density of 20 J/cm² is performed, dendritic structure portion 104 is formed on the surface of first depression 103 formed on metal member 101, and dendritic structure portion 104 is composed of oxidized Al. On the other hand, FIGS. 8(a) to 8(c) are results of cross-sectional analysis on metal member 101 after irradiation. with a laser having an energy density of 50 J/cm². FIG. 8(a) shows a result of cross-sectional TEM analysis, FIG. 8(b) shows a result of cross-sectional TEM-EDX analysis showing distribution of Al element, and FIG. 8(c) shows a result of cross-sectional TEM-EDX analysis showing distribution of O element. The results shown in FIGS. 8(a) to 8(c) show that in a case where irradiation with a laser having an energy density of 50 J/cm² is performed, dendritic structure portion 104 is not formed on the surface of first depression 103 formed on metal member 101. This is presumed to be because Al of metal member 101 irradiated with a laser is melted or vaporized without forming dendritic structure portion 104 as a result of the energy density of the emitted laser being too high.

From such observation results, it is considered that an oxide of metal member 101 generated due to the ablation of metal member 101 by the laser irradiation mainly compose dendritic structure portion 104.

Next, a result of fatigue strength testing using a joint body manufactured as an example of the first embodiment and a joint body manufactured as a comparative example will be shown.

### Example of First Embodiment

First, a configuration of an example of the first embodiment will be described with reference to FIGS. 2(a) to 2(d).

In FIG. 2(a), aluminum A5052 having its surface degreased with acetone was prepared as metal member 101.

In FIG. 2(b), a range of 20 mm×20 mm of metal member 101 was irradiated with a pulsed laser. For the pulsed laser irradiation, MX-Z2000H (wavelength: 1,062 nm, diameter of laser spot: about 45 μm) manufactured by OMRON Corporation was used. At this time, the frequency and the speed were adjusted so as to make adjacent laser spots contiguous to each other, in other words, make the distance equal to 1.0 times the diameter of the laser spot. The energy density of the laser to be emitted was set to 20 J/cm², and first depression 103 and dendritic structure portion 104 were formed at the irradiated portion.

In FIG. 2(c), first depression 103 was formed on the surface of metal member 101 by the laser irradiation, and had a width of about 50 μm and a depth of about 10 μm. Further, dendritic structure portion 104 was formed, with a thickness of about 200 nm, all over the range of 20 mm×20 mm irradiated with a laser.

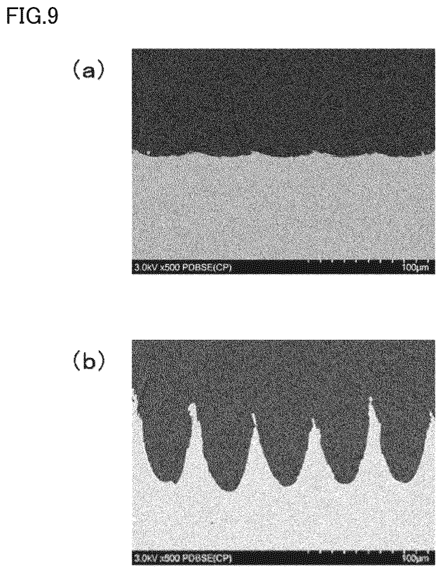

Thereafter, in FIG. 2(d), a liquid epoxy resin (manufactured by Ryoden Kasei Co., Ltd.) was potted in a cylindrical shape with a diameter of 5 mm on the surface of metal member 101 irradiated with a laser, and heated and cured at 180° C. to form resin member 102, thereby obtaining joint body 100. FIG. 9(a) is a cross-sectional SEM image of the joint body manufactured as the example.

Initial adhesive strength testing and fatigue strength testing were performed on the joint body thus obtained. In the initial adhesive strength testing, a load is applied to a portion having a height of 1 mm from a joint interface of joint body 100 toward resin member 102 in a direction parallel to the joint surface at a speed of 1 mm/sec, and shear strength was evaluated. As a result, shear joint strength was 28.9 MPa. Further, a broken point was found in resin member 102.

Next, in the fatigue strength testing, a load with a stress amplitude of 2.8 MPa was applied to the portion having a height of 1 mm from the joint interface of joint body toward resin member 102, and fatigue strength was evaluated. As a result, the number of breaking cycles of the joint body was 4.9×10⁶ cycles. Further, a broken point was found in resin member 102.

### Comparative Example

A configuration of a comparative example will be described with reference to FIGS. 2(a) to 2(d).

In FIG. 2(a), aluminum A5052 having its surface degreased with acetone was prepared as metal member 101.

In FIG. 2(b), a range of 20 mm×20 mm of metal member 101 was irradiated with a pulsed laser. For the pulsed laser irradiation, MX-Z2000H (wavelength: 1,062 nm, diameter of laser spot: about 45 μm) manufactured by OMRON Corporation was used. At this time, the frequency and the speed were adjusted so as to make adjacent laser spots contiguous to each other, in other words, make the distance equal to 1.0 times the diameter of the laser spot. The energy density of the laser to be emitted was set to 50 J/cm², and the same portion was irradiated 10 times. Dendritic structure portion 104 was not formed at the irradiated portion, and only first depression 103 was formed.

In FIG. 2(c), first depression 103 was formed on the surface of metal member 101 by the laser irradiation, and had a width of about 50 μm and a depth of about 70 μm.

Thereafter, in FIG. 2(d), a liquid epoxy resin (manufactured by Ryoden Kasei Co., Ltd.) was potted in a cylindrical shape with a diameter of 5 mm on the surface of metal member 101 irradiated with a laser, and heated and cured at 180° C. to form resin member 102, thereby obtaining joint body 100. FIG. 9(b) is a cross-sectional SEM image of the joint body manufactured as the comparative example.

Initial adhesive strength testing and fatigue strength testing were performed on the joint body thus obtained. In the initial adhesive strength testing, a load is applied to a portion having a height of 1 mm from a joint interface of the joint body toward resin member 102 in a direction parallel to the joint surface at a speed of 1 mm/sec, and shear strength was evaluated. As a result, shear joint strength was 32.2 MPa. Further, a broken point was found in resin member 102.

Next, in the fatigue strength testing, a load with a stress amplitude of 2.8 MPa was applied to the portion having a height of 1 mm from the joint interface of joint body toward resin member 102, and fatigue strength was evaluated. As a result, the number of breaking cycles of the joint body was 1.0×10⁶ cycles. Further, a broken point was found in the joint interface between metal member 101 and resin member 102.

Therefore, the comparison between the results of the fatigue strength testing showed that the joint body manufactured as the example is about 5 times greater in the number of breaking cycles than the joint body manufactured as the comparative example, and is longer in fatigue life. Further, the broken point of the joint body manufactured as the example was found in resin member 102, whereas the broken point of the joint body manufactured as the comparative example was found in the joint interface between metal member 101 and resin member 102. Therefore, it showed that it is possible to obtain, by applying the first embodiment, a resin-metal joint body having higher strength and longer durability.

As described above, the resin-metal joint body according to the first embodiment includes metal member 101 and resin member 102 joined to metal member 101, metal member 101 has dendritic structure portion 104 on the surface joined to resin member 102, at least a part of dendritic structure portion 104 has a nanometer-order diameter, and resin member 102 permeates through dendritic structure portion 104.

Such a configuration can ensure an adequate contact area between resin member 102 and nanometer-order dendritic structure portion 104 formed on metal member 101, so that it is possible to obtain joint body 100 in which metal member 101 and resin member 102 are firmly joined together.

Further, the production method for joint body 100 according to the first embodiment includes the surface treatment process of forming first depression 103 and dendritic structure portion 104, at least a part of dendritic structure portion 104 having a nanometer-order diameter, on the surface of metal member 101, and the joining process of causing resin member 102 to permeate through dendritic structure portion 104 to join metal member 101 and resin member 102 together.

Such a configuration can ensure an adequate contact area between resin member 102 and nanometer-order dendritic structure portion 104 formed on metal member 101 and provide the production method for joint body 100 in which metal member 101 and resin member 102 are firmly joined together.

### Second Embodiment

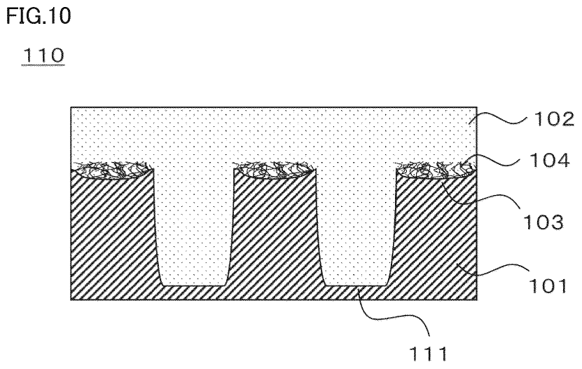

FIG. 10 is a schematic cross-sectional view of a joint body 110 according to a second embodiment.

As illustrated in FIG. 10, joint body 110 is a joint body of metal member 101 and resin member 102, and is different from joint body 110 according to the first embodiment in that a second depression 111 is formed in addition to first depression 103 on the surface, that is a joining portion, of metal member 101. The other configuration is the same as in the first embodiment.

As in the first embodiment, a plurality of first depressions 103 are formed on the surface joined to resin member 102, and dendritic structure portion 104 is formed on the surface of each first depression 103. A plurality of second depressions 111 are formed on the surface joined to resin member 102, and are formed deeper than first depression 103, so that metal member 101 and resin member 102 are more firmly joined together due to an anchor effect. Note that a depth of second depression 111 is not particularly limited as long as second depression 111 is deeper than first depression 103, but is more preferably greater than or equal to 50 μm. On the other hand, dendritic structure portion 104 is not formed on the surface of second depression 111. Abundance ratios of first depression 103 and second depression 111 formed on the surface of metal member 101 are not particularly limited, but are each preferably about 50%. Further, a positional relationship between first depression 103 and second depression 111 formed on the surface of metal member 101 is not particularly limited, but it is preferable that both first depression 103 and second depression 111 are formed evenly on the surface of metal member 101, and it is more preferable that first depression 103 and second depression 111 are alternately formed.

In joint body 110 configured as described above, resin member 102 permeates through dendritic structure portion 104 formed on first depression 103, so as to ensure an adequate contact area between resin member 102 and dendritic structure portion 104. Further, molecules constituting resin member 102 and molecules constituting dendritic structure portion 104 come close to each other on the order of nanometers to produce an intermolecular force, so that resin member 102 and dendritic structure portion 104 are firmly joined together. Furthermore, it is possible to obtain an anchor effect produced by resin member 102 entering second depression 111 deeper than first depression 103 in joint body 110, so that metal member 101 and resin member 102 are more firmly joined together.

As described above, with the configuration described in the second embodiment, not only the same effect as in the first embodiment, but also the anchor effect can be obtained due to resin member 102 entering second depression 111 deeper than first depression 103, so that it is possible to obtain a resin-metal joint body joined more firmly.

Next, a production process according to the second embodiment will be described.

The joint body production process according to the second embodiment is different from the joint body production process according to the first embodiment in that second depression 111 is formed on the surface of metal member 101 in addition to first depression 103 and dendritic structure portion 104 in the surface treatment process described in the first embodiment. The other processes are the same as in the first embodiment.

It is possible to form, by repeatedly irradiating the surface of metal member 101 with a laser, second depression 111 deeper than first depression 103, preferably to a depth of greater than or equal to 50 μm. The laser to be emitted is not particularly limited, but a pulsed laser similar to the laser used to form first depression 103 and dendritic structure portion 104 is preferable.

Note that the method for forming first depression 103 and dendritic structure portion 104 is the same as in the first embodiment, so that the description of the method will be omitted. Further, first depression 103 and dendritic structure portion 104 may be formed first, or alternatively, second depression 111 may be formed first. It is possible to obtain joint body 110 by applying the joining process described

in the first embodiment to join resin member 102 to the joint surface, obtained as described above, of metal member 101 on which first depression 103 having dendritic structure portion 104 and second depression 111 are formed.

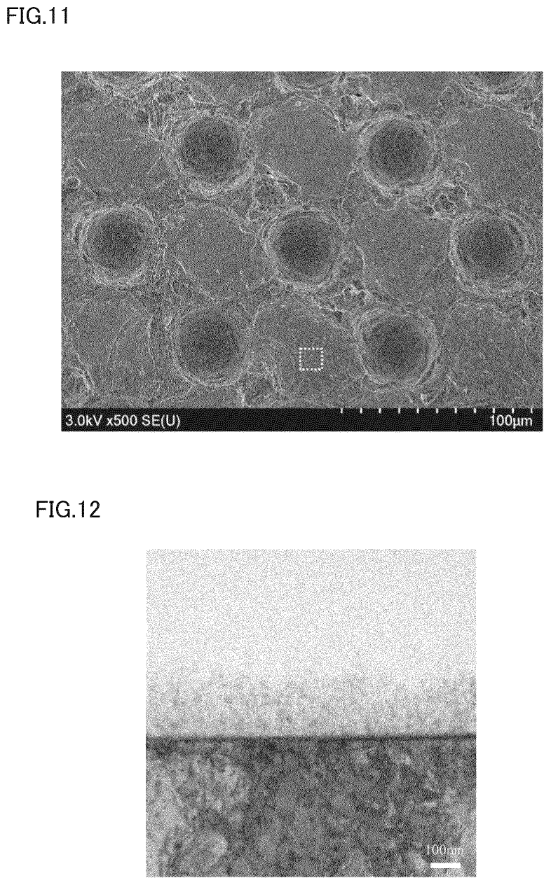

Next, FIGS. 11 and 12 each show a result of observing the surface and cross section of metal member 101 obtained in the second embodiment.

FIG. 11 is an SEM image of the surface of metal member 101 according to the second embodiment. FIG. 11 shows an example where first depression 103 and second depression 111 are formed adjacent to each other but without overlapping each other and in contact with each other without a gap. This example is obtained by making spot diameters of a laser emitted to form first depression 103 and second depression 111 equal to each other and forming first depression 103 and second depression 111 apart from each other by a distance twice the spot diameter.

FIG. 12 is a TEM image of a cross section of first depression 103 of metal member 101 according to the second embodiment. More specifically, a cross section of a rectangular region indicated by a dashed line in FIG. 11 is shown. It can be seen that dendritic structure portion 104 having a thickness of about several 100 nm from the surface of first depression 103 is formed on the surface of first depression 103.

Next, a result of evaluating joint strength using a joint body manufactured as an example of the second embodiment will be described.

### Example of Second Embodiment

Although not illustrated, a configuration of the example of the second embodiment will be described following the same flow as of the example of the first embodiment.

First, aluminum A5052 having its surface degreased with acetone was prepared as metal member 101.

Next, first depression 103 having dendritic structure portion 104 and second depression 111 were formed on metal member 101. In order to form second depression 111, a range of 20 mm×20 mm of metal member 101 was irradiated with a pulsed laser. For the pulsed laser irradiation, MX-Z2000H (wavelength: 1,062 nm, diameter of laser spot: about 45 μm) manufactured by OMRON Corporation was used. At this time, the frequency and the speed were adjusted so as to make the laser spots adjacent to each other at intervals twice the diameter of each laser spot. The energy density of the laser to be emitted was set to 200 J/cm², and second depression 111 having a depth of about 50 μm was formed at the irradiated portion. Subsequently, metal member 101 having second depression 111 formed thereon was irradiated with a pulsed laser. At this time, the frequency and the speed were adjusted so as to prevent adjacent laser spots from overlapping second depression 111. The energy density of the laser to be emitted was set to 20 J/cm², and first depression 103 having dendritic structure portion 104 was formed at the irradiated portion.

As a result of the surface treatment by means of laser irradiation, first depression 103 having dendritic structure portion 104 and second depression 111 were alternately formed on the surface of metal member 101. First depression 103 and second depression 111 each had a width of about 50 μm, and first depression 103 had a depth of about 10 μm. Further, dendritic structure portion 104 had a thickness of about 200 nm.

Subsequently, a liquid epoxy resin (manufactured by Ryoden Kasei Co., Ltd.) was potted in a cylindrical shape with a diameter of 5 mm on the surface of metal member 101 subjected to the surface treatment, and heated and cured at 180° C. to form resin member 102, thereby obtaining joint body 110.

Initial adhesive strength testing was performed on the joint body thus obtained. In the initial adhesive strength testing, a load is applied to a portion having a height of 1 mm from the joint interface of joint body 110 toward resin member 102 in a direction parallel to the joint surface at a speed of 1 mm/sec, and shear strength was evaluated.

As a result, shear joint strength was 33.0 MPa. Further, a broken point was found in resin member 102.

Therefore, it showed that the joint body manufactured in the example of the second embodiment is higher in initial joint strength than the joint body manufactured in the comparative example of the first embodiment, as in the example of the first embodiment. Thus, it showed that it is possible to obtain, by applying the second embodiment, a resin-metal joint body having higher strength and longer durability as in the first embodiment and further having higher initial joint strength.

As described above, in the resin-metal joint body according to the second embodiment, in addition to the configuration of the first embodiment, metal member 101 has depressions on the surface joined to resin member 102, the depressions include first depression 103 having dendritic structure portion 104 on the surface and second depression 111 deeper than first depression 103, and first depression 103 and second depression 111 are alternately formed.

Such a configuration can ensure an adequate contact area between resin member 102 and nanometer-order dendritic structure portion 104 formed on metal member 101 and cause resin member 102 to enter second depression 111 deeper than first depression 103. It is thus possible to obtain, in addition to the same effect as in the first embodiment, the anchor effect produced by second depression 111, so that it is possible to obtain joint body 110 in which metal member 101 and resin member 102 are more firmly joined together.

### Third Embodiment

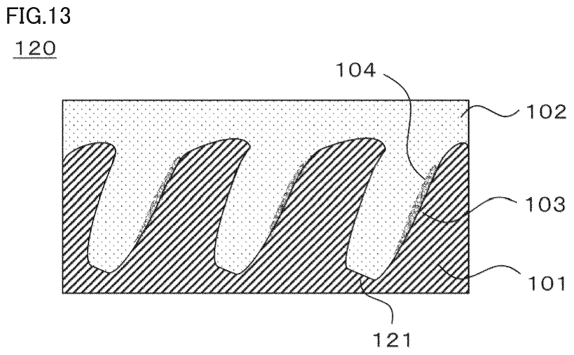

FIG. 13 is a schematic cross-sectional view of a joint body 120 according to a third embodiment.

As illustrated in FIG. 13, joint body 120 is different from the joint body according to the first embodiment in that a third depression 121 is formed on the surface, that is a metal member joining portion, of metal member 101, and first depression 103 having dendritic structure portion 104 is formed on the surface of third depression 121. The other configuration is the same as in the first embodiment.

Third depression 121 is formed at an angle relative to the surface of metal member 101, is deeper than first depression 103, and first depression 103 is formed on the surface of third depression 121. Further, as in the first embodiment, dendritic structure portion 104 is formed on the surface of first depression 103. Further, a plurality of third depressions 121 are formed on the surface of metal member 101 to be joined to resin member 102. Note that the depth of third depression 121 is not particularly limited as long as third depression 121 is deeper than first depression 103, but is preferably greater than or equal to 50 μm. Further, an abundance ratio of first depression 103 to the surface area of third depression 121 is not particularly limited, but is preferably greater than or equal to 10%. Furthermore, the angle of third depression 121 relative to the surface of metal member 101 is not particularly limited, but is preferably less than 90 degrees because first depression 103 is formed on the surface of third depression 121.

In joint body 120 configured as described above, the anchor effect due to resin member 102 entering third depression 121 that is formed at an angle relative to the surface of metal member 101 and is deeper than first depression 103 can be obtained. Furthermore, first depression 103 having dendritic structure portion 104 is formed on the surface of third depression 121 that produces the anchor effect, and resin member 102 permeates through dendritic structure portion 104, thereby making it possible to ensure an adequate contact area. It is therefore possible to obtain a stronger anchor effect by joining resin member 102 and dendritic structure portion 104 together, so that metal member 101 and resin member 102 are firmly joined together as compared with a case where dendritic structure portion 104 is not provided.

As described above, the configuration described in the third embodiment can ensure an adequate contact area between resin member 102 and dendritic structure portion 104 on the surface of third depression 121 and can obtain a stronger anchor effect, so that a resin-metal joint body joined firmly as compared with the conventional anchor effect can be obtained.

Next, a production process according to the third embodiment will be described.

The joint body production process according to the third embodiment is different from the joint body production process according to the first embodiment in that third depression 121 is formed on the surface of metal member 101, and first depression 103 and dendritic structure portion 104 are formed on the surface of third depression 121 in the surface treatment process described in the first embodiment. The other processes are the same as in the first embodiment.

Repeatedly irradiating the surface of metal member 101 with a laser forms third depression 121 that is deeper than first depression 103. An angle of the laser to be emitted is not particularly limited as long as the laser is at an angle relative to the surface of metal member 101, but is preferably about 45 degrees. Further, the laser to be emitted is not particularly limited, but a pulsed laser similar to the laser used to form first depression 103 and dendritic structure portion 104 is preferable.

After third depression 121 is formed on the surface of metal member 101, third depression 121 is irradiated with the pulsed laser to form first depression 103 having dendritic structure portion 104. Note that the method for forming first depression 103 and dendritic structure portion 104 is the same as in the first embodiment, so that the description of the method will be omitted.

It is possible to obtain joint body 120 by applying the joining process described in the first embodiment to join resin member 102 to the joint surface, obtained as described above, of metal member 101 on which the third depression is formed.

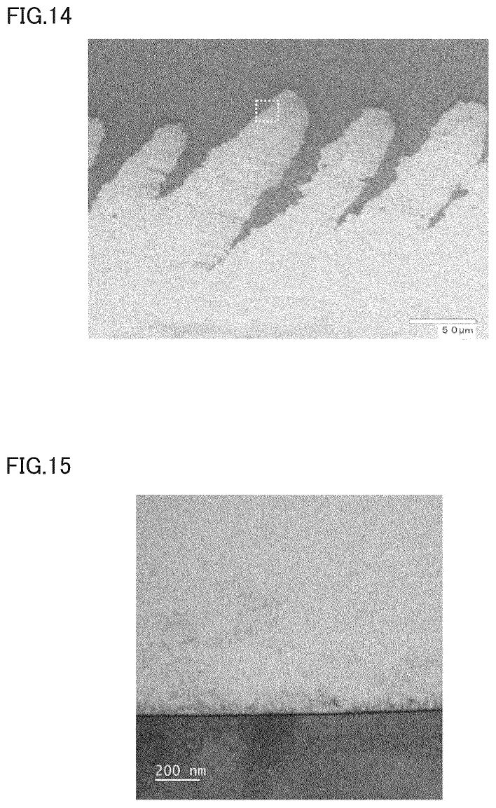

Next, FIGS. 14 and 15 each show a result of observing the cross section of the surface of metal member 101 obtained in the third embodiment.

FIG. 14 is an SEM image of the cross section of the surface of metal member 101 obtained in the third embodiment. More specifically, the SEM image shows the cross section of the surface of metal member 101 obtained by forming third depression 121 having a depth of 50 μm at an angle of 45 degrees relative to the surface and forming first depression 103 having dendritic structure portion 104 on the surface of third depression 121.

FIG. 15 is a TEM image of the cross section of first depression 103 of metal member 101 obtained in the third embodiment. More specifically, this shows a cross section of a rectangular region indicated by a dashed line in FIG. 14. It can be seen that dendritic structure portion 104 having a thickness of about several 100 nm from the surface of first depression 103 is formed on the surface of first depression 103.

Next, a result of evaluating joint strength using a joint body manufactured as an example of the third embodiment will be described.

### Example of Third Embodiment

Although not illustrated, a configuration of the example of the third embodiment will be described following a flow similar to the flow of the example of the first embodiment.

First, aluminum A5052 having its surface degreased with acetone was prepared as metal member 101.

Next, third depression 121 was formed on metal member 101, and first depression 103 having dendritic structure portion 104 was formed on the surface of third depression 121. In order to form third depression 121, metal member 101 was placed at an angle of 45 degrees relative to a laser, and a range of 20 mm×20 mm was irradiated with a pulsed laser. For the pulsed laser irradiation, MX-Z2000H (wavelength: 1,062 nm, diameter of laser spot: about 45 μm) manufactured by OMRON Corporation was used. At this time, the frequency and the speed were adjusted so as to make adjacent laser spots contiguous to each other. The energy density of the laser to be emitted was set to 200 J/cm², and third depression 121 having a depth of about 50 μm was formed at the irradiated portion. Subsequently, the surface of third depression 121 was irradiated with a pulsed laser. At this time, the frequency and the speed were adjusted so as to make adjacent laser spots contiguous to each other. The energy density of the laser to be emitted was set to 20 J/cm², and first depression 103 having dendritic structure portion 104 was formed at the irradiated portion on the surface of third depression 121.

As a result of the surface treatment by means of laser irradiation, third depression 121 was formed on the surface of metal member 101, and first depression 103 having dendritic structure portion 104 was formed on the surface of third depression 121. First depression 103 had a depth of about 10 μm as in the example of the first embodiment and the example of the second embodiment. Further, dendritic structure portion 104 had a thickness of about 200 nm.

Subsequently, a liquid epoxy resin (manufactured by Ryoden Kasei Co., Ltd.) was potted in a cylindrical shape with a diameter of 5 mm on the surface of metal member 101 subjected to the surface treatment, and heated and cured at 180° C. to form resin member 102, thereby obtaining joint body 120.

Initial adhesive strength testing was performed on the joint body thus obtained. In the initial adhesive strength testing, a load is applied to a portion having a height of 1 mm from the joint interface of joint body 120 toward resin member 102 in a direction parallel to the joint surface at a speed of 1 mm/sec, and shear strength was evaluated. As a result, shear joint strength was 32.8 MPa. Further, a broken point was found in resin member 102.

Therefore, it showed that the joint body manufactured in the example of the third embodiment is higher in initial joint strength than the joint body manufactured in the comparative example of the first embodiment, as in the example of the first embodiment. Thus, it showed that it is possible to obtain, by applying the third embodiment, a resin-metal joint body having higher strength and longer durability as in the first embodiment and further having higher initial joint strength.

Note that, in the production process according to the third embodiment, the case where third depression 121 is at an angle of 45 degrees relative to the surface of metal member 101, that is, inclined relative to the surface has been described, but third depression 121 may be at an angle of 90 degrees relative to the surface of metal member 101, that is, perpendicular to the surface. In a case where third depression 121 is perpendicular to the surface of metal member 101, first depression 103 having dendritic structure portion 104 is formed on a deep portion on the surface of third depression 121 as compared with a case where third depression 121 is at an angle relative to the surface, but it is possible to obtain a similar effect by causing resin member 102 to permeate through dendritic structure portion 104.

Further, in the method for forming third depression 121 at an angle of 90 degrees relative to the surface of metal member 101, it is possible to form third depression 121 by setting the laser irradiation angle at the time of forming third depression 121 to 90 degrees relative to the surface of metal member 101 in the forming method described in the third embodiment. First, third depression 121 is formed at an angle of 90 degrees relative to the surface of metal member 101, and the surface of third depression 121 thus formed is irradiated with a laser to form first depression 103 having dendritic structure portion 104 on the surface. As described above, it is possible to obtain metal member 101 on which third depression 121 is formed at an angle of 90 degrees relative to the surface. Subsequently, as in the other embodiments, it is possible to obtain, by forming resin member 102 on the surface of metal member 101, joint body 120 having third depression 121 at an angle of 90 degrees relative to the surface of metal member 101.

As described above, in the resin-metal joint body according to the third embodiment, in addition to the configuration of the first embodiment, metal member 101 has depressions on the surface joined to resin member 102, the depressions include third depression 121 formed at an angle relative to the surface of metal member 101 and first depression 103 formed on the surface of third depression 121, and first depression 103 has dendritic structure portion 104 formed on its surface.

Such a configuration can cause resin member 102 to enter third depression 121 formed on metal member 101 and ensure an adequate contact area between resin member 102 and nanometer-order dendritic structure portion 104 formed on the surface of first depression 103. It is thus possible to obtain the anchor effect that achieves stronger joining, so that it is possible to obtain joint body 120 in which metal member 101 and resin member 102 are more firmly joined together.

### Fourth Embodiment

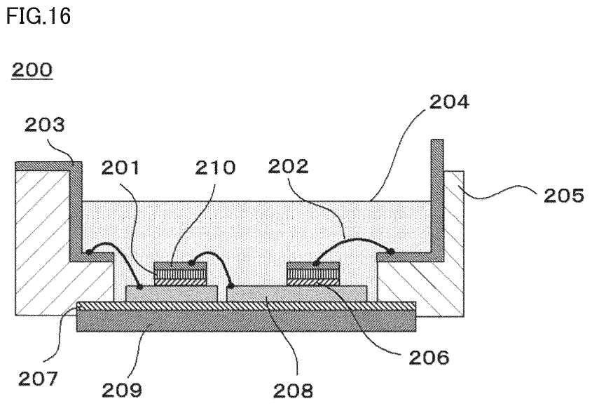

FIG. 16 is a schematic cross-sectional view of a semiconductor device 200 according to a fourth embodiment.

As illustrated in FIG. 16, in semiconductor device 200, a semiconductor element 201 is mounted on an insulating substrate 207, and a surface of insulating substrate 207 opposite to a surface on which semiconductor element 201 is mounted is joined to a heat spreader 209.

Semiconductor element 201 includes a semiconductor substrate such as silicon (Si), silicon carbide (SiC), or gallium nitride (GaN) and an insulated gate bipolar transistor (IGBT), a diode (Di), or the like formed on the semiconductor substrate. Note that semiconductor element 201 is not limited to the above-described configuration, and may be, for example, an insulated gate field effect transistor (MOSFET) or a high electron mobility transistor (HEMT). Further, a plurality of semiconductor elements 201 may be provided, or a plurality of types of semiconductor elements may be mounted. A conductive layer 208 formed of a metal member is provided on a surface of insulating substrate 207, and semiconductor element 201 is joined to conductive layer 208 with solder 206. Insulating substrate 207 is made of, for example, aluminum nitride (AIN). A resin case 205 is fixed to insulating substrate 207 on which semiconductor element 201 is mounted. An electrode terminal 203 formed of a metal member is attached to resin case 205. Resin case 205 is formed of, for example, a poly phenylene sulfide resin. Electrode terminal 203 and a surface electrode 210 formed of a metal member are electrically connected by a wire 202. Wire 202 is a wire using a conductive metal member such as Au or Al, and connects electrode terminal 203 and surface electrode 210 by wire bonding. Here, first depression 103 is formed on at least a part of the surfaces of surface electrode 210, electrode terminal 203, and conductive layer 208, and dendritic structure portion 104 is formed on the surface of first depression 103. The depth of first depression 103 to the bottom is preferably in a range of greater than 100 nm and less than 10 μm, and a ratio of the depth to the width of first depression 103 is preferably greater than or equal to 0.002 and less than or equal to 0.2. Further, the thickness of dendritic structure portion 104 is preferably in a range of greater than or equal to 1/1000 and less than or equal to 1/100 of the width of first depression 103, and furthermore, the thickness of dendritic structure portion 104 is preferably in a range of greater than or equal to 1/100 and less than or equal to 1/10 of the depth of first depression 103. Furthermore, semiconductor device 200 is encapsulated in a resin member 204 as an encapsulation resin. Resin member 204 permeates through dendritic structure portion 104 formed on at least a part of the surfaces of surface electrode 210, electrode terminal 203, and conductive layer 208 to form a resin-metal joint body.

In the semiconductor device configured as described above, resin member 204 permeates through dendritic structure portion 104, so that it is possible to ensure an adequate contact area between resin member 204 and dendritic structure portion 104. Further, molecules constituting resin member 204 and molecules constituting dendritic structure portion 104 come close to each other on the order of nanometers to produce an intermolecular force, so that resin member 204 and dendritic structure portion 104 are firmly joined together.

As described above, the configuration given in the fourth embodiment makes it possible to obtain a semiconductor device encapsulated in resin having higher strength and longer durability without using functional molecules or the like while suppressing a decrease in productivity due to formation of a structure for obtaining the anchor effect.

Next, an example of a production method for semiconductor device 200 described above will be described.

First, insulating substrate 207 is prepared. Conductive layer 208 formed of a metal member is provided on the surface of insulating substrate 207. Semiconductor clement 201 is placed on conductive layer 208 with solder 206 interposed between semiconductor element 201 and conductive layer 208, and semiconductor element 201 is joined to conductive layer 208 by reflow processing. As a result, semiconductor element 201 and conductive layer 208 are electrically connected. Here, as semiconductor element 201, a semiconductor element having first depression 103 and dendritic structure portion 104 formed in advance on surface electrode 210 formed of a metal member may be used. It is preferable that first depression 103 and dendritic structure portion 104 be formed by irradiation with a pulsed laser. Further, in order to avoid first depression 103 and dendritic structure portion 104 from being deformed or the like due to heat, it is preferable that the pulse width be as short as possible. Specifically, it is preferable that the pulse width be less than or equal to 10 ns. Further, the wavelength of the pulsed laser is not particularly limited, but as an example of the wavelength suitable for metal processing, a wavelength of greater than or equal to 200 nm and less than or equal to 10,000 nm is preferable, and a wavelength of greater than or equal to 400 nm and less than or equal to 2,000 nm is more preferable. Further, energy density of the pulsed laser emitted per unit area is preferably in a range of greater than or equal to 0.5 J/cm² and less than or equal to 50 J/cm². Furthermore, the energy density is more preferably in a range of greater than or equal to 5 J/cm² and less than or equal to 30 J/cm². In a case where the energy density is less than 5 J/cm², the amount of energy being supplied is too small to form first depression 103 and dendritic structure portion 104. On the other hand, in a case where the energy density is greater than 30 J/cm², the energy being supplied becomes excessive to cause dendritic structure portion 104 to melt, and only first depression 103 is formed. Further, if necessary, the laser irradiation may be performed in a gas atmosphere such as N₂, Ar, or He. Laser irradiation under an atmosphere of inert gas can inhibit, for example, surface electrode 210, first depression 103, and dendritic structure portion 104 from being subject to oxidation, so that it is also applicable to control of wettability of surface electrode 210, first depression 103, and dendritic structure portion 104 after the laser irradiation. Furthermore, for the purpose of cooling, it is also possible to perform the laser irradiation while supplying an inert gas. Furthermore, not only surface electrode 210 but also conductive layer 208 may be irradiated with the above-described pulsed laser to form first depression 103 and dendritic structure portion 104 on the surface of conductive layer 208.

Next, electrode terminal 203 formed of a metal member and semiconductor element 201 are electrically connected by wire 202 formed of a metal member. Wire 202 is joined to electrode terminal 203 and semiconductor element 201 by, for example, a wire bonding device. Further, electrode terminal 203 and conductive layer 208 are electrically connected by wire 202 in a similar manner. Note that as wire 202, a wire having first depression 103 and dendritic structure portion 104 formed in advance by the above-described pulsed laser irradiation may be used.

Next, insulating substrate 207, semiconductor element 201 mounted on insulating substrate 207, and the like are encapsulated in resin member 204. As resin member 204, for example, a liquid encapsulating material such as an epoxy resin is used, and is poured into resin case 205 until semiconductor element 201 mounted on insulating substrate 207 and wire 202 are completely covered, and is hardened by heat treatment.

As described above, first depression 103 and dendritic structure portion 104 are formed in at least a part of surface electrode 210, conductive layer 208, electrode terminal 203, and wire 202 each formed of a metal member, and a portion where first depression 103 and dendritic structure portion 104 are formed and resin member 204 are firmly joined together.

Therefore, in the semiconductor device according to the fourth embodiment, the surface electrode, the conductive layer, the electrode terminal, or the wire is encapsulated in the resin member, and at least a part of a joint body of the surface electrode, the conductive layer, the electrode terminal, or the wire and the resin member includes the joint body according to the first embodiment.

With such a configuration, it is possible to ensure an adequate contact area between resin member 204 and nanometer-order dendritic structure portion 104 provided on surface electrode 210, conductive layer 208, electrode terminal 203, and wire 202 each formed of a metal member, so that it is possible to obtain semiconductor device 200 including a joint body in which surface electrode 210, conductive layer 208, electrode terminal 203, and wire 202 are firmly joined to resin member 204.

Note that the embodiments disclosed herein are illustrative and are not construed as limiting the present disclosure. For example, semiconductor device 200 may be manufactured by irradiating, immediately before the encapsulation in resin member 204, at least a part of surface electrode 210, conductive layer 208, electrode terminal 203, and the wire member with a pulsed laser to form first depression 103 and dendritic structure portion 104.

Furthermore, the present disclosure is a technique that is widely applicable not only to the above-described semiconductor device but also to a field where resin metal joining is used. Examples of components to which the resin metal joining is applied include a vehicle component, an electric railway component, an elevator component, an aircraft component, an artificial satellite component, an optical communication component, an industrial robot component, a generator component, an air-conditioning equipment component, and a home appliance component.

### REFERENCE SIGNS LIST

100: joint body, 101: metal member, 102: resin member, 103: first depression, 104: dendritic structure portion, 110: joint body, 111: second depression, 120: joint body, 121: third depression, 200: semiconductor device, 201: semiconductor element, 202: wire, 203: electrode terminal, 204: resin member, 205: resin case, 206: solder, 207: insulating substrate, 208: conductive layer, 209: heat spreader, 210: surface electrode

1. A joint body comprising:
a metal member: and
a resin member joined to the metal member,
wherein
the metal member has a dendritic structure portion on a surface joined to the resin member,
at least a part of the dendritic structure portion has a nanometer-order diameter, and
the resin member permeates through the dendritic structure portion.

2. The joint body according to claim 1, wherein the metal member has a depression on the surface joined to the resin member,
the dendritic structure portion includes a dendritic body, and
the dendritic structure portion spatially spreads so as to cause dendritic bodies adjacent to each other to intertwine.

3. The joint body according to claim 2, wherein the depression has a depth of less than or equal to 10 μm.

4. The joint body according to claim 3, wherein a ratio (X/Y) of the depth (X) to a width (Y) is less than or equal to 0.2.

5. The joint body according to claim 2, wherein
the dendritic structure portion is formed on a surface of the depression, and
the dendritic structure portion has a thickness of less than or equal to 1/100 of a width of the depression.

6. The joint body according to claim 2, wherein the dendritic structure portion has the thickness of less than or equal to 1/10 of a depth of the depression.

7. The joint body according to claim 2, wherein the dendritic structure portion is formed around the depression.

8. A semiconductor device comprising a surface electrode, a conductive layer, an electrode terminal, or a wire, the surface electrode, the conductive layer, the electrode terminal, or the wire being encapsulated in a resin member,
wherein
the surface electrode, the conductive layer, the electrode terminal, or the wire are metal members, and
at least a part of a joint body of the surface electrode, the conductive layer, the electrode terminal, or the wire and the resin member is the joint body according to claim 1.

9. A joint body production method comprising:
a surface treatment process of forming a depression and a dendritic structure portion on a surface of a metal member, at least a part of the dendritic structure portion having a nanometer-order diameter; and
a joining process of causing a resin member to permeate through the dendritic structure portion to join the metal member and the resin member together,
wherein the surface treatment process is performed by irradiating one region with a single pulsed laser, and
the surface treatment process is performed by the pulsed laser having a pulse width of less than or equal to 10 ns and an energy density of greater than or equal to 5 J/cm² and less than or equal to 30 J/cm².

10. (canceled)

11. The joint body according to claim 2, wherein the depression includes a first depression having the dendritic structure portion on a surface and a second depression deeper than the first depression, and the first depression and the second depression are alternatively formed.

12. The joint body according to claim 2, wherein the depression includes a third depression formed at an angle relative to a surface of the metal member and a first depression formed on a surface of the third depression, and the dendritic structure portion is formed on a surface of the first depression.

13. The joint body according to claim 12, wherein the third depression is at an angle of less than 90 degrees relative to the surface of the metal member.
